(19) United States
(12) Patent Application Publication
(10) Pub. No.: US 2025/0104796 A1
(43) Pub. Date: Mar. 27, 2025

(54) PERFORMING CORRECTIVE SENSE OPERATIONS IN MEMORY

(71) Applicant: Micron Technology, Inc., Boise, ID (US)

(72) Inventors: Jun Wan, San Jose, CA (US); Yu-Chung Lien, San Jose, CA (US); Zhenming Zhou, San Jose, CA (US)

(21) Appl. No.: 18/786,016

(22) Filed: Jul. 26, 2024

Related U.S. Application Data
(60) Provisional application No. 63/540,806, filed on Sep. 27, 2023.

(51) Int. Cl. G11C 29/52; G11C 16/34

(52) U.S. Cl. CPC G11C 29/52; G11C 16/3404; G11C 16/3418

(57) ABSTRACT

Devices, methods, and systems for performing corrective sense operations in memory are described herein. An example apparatus includes a memory component including a plurality of groups of memory cells, and a processing device coupled to the memory component and configured to perform a sense operation on the plurality of groups of memory cells, perform a corrective sense operation on a first one of the plurality of groups of memory cells using a corrective value, and perform the corrective sense operation on a second one of the plurality of groups of memory cells using the corrective value.

### PRIORITY INFORMATION

This application claims the benefits of U.S. Provisional Application No. 63/540,806, filed on Sep. 27, 2023, the contents of which are incorporated herein by reference.

### TECHNICAL FIELD

Embodiments of the disclosure relate generally to memory sub-systems, and more specifically, relate to performing corrective sense operations in memory.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system in accordance with some embodiments of the present disclosure.

FIG. 2A illustrates a diagram of a number of initial threshold voltage distributions associated with groups of memory cells in accordance with some embodiments of the present disclosure.

FIG. 2B illustrates a diagram of a number of threshold voltage distributions associated with the groups of memory cells before a corrective sense operation, and a number of threshold voltage distributions associated with the groups of memory cells after the corrective sense operation, in accordance with some embodiments of the present disclosure.

FIG. 3A illustrates a conceptual example of binning groups of memory cells together for corrective sense operations in accordance with some embodiments of the present disclosure.

FIG. 3B illustrates an additional conceptual example of binning groups of memory cells together for corrective sense operations in accordance with some embodiments of the present disclosure.

FIG. 4 is a block diagram of an example computer system in which embodiments of the present disclosure can operate in accordance with some embodiments of the present disclosure.

### DETAILED DESCRIPTION

Aspects of the present disclosure are directed to performing corrective sense operations in memory. An example apparatus includes a memory component including a plurality of groups of memory cells, and a processing device coupled to the memory component and configured to perform a sense operation on the plurality of groups of memory cells, perform a corrective sense operation on a first one of the plurality of groups of memory cells using a corrective value, and perform the corrective sense operation on a second one of the plurality of groups of memory cells using the corrective value.

In various memory sub-systems, programming memory cells can involve providing a programming signal to a group of cells (e.g., a page) to place them in target states, which correspond to respective stored data patterns. For example, the cells can be non-volatile flash memory cells configured to store one or more bits of data per cell. Additionally, a memory sub system can utilize a corrective sense (e.g., read) operation to downshift or upshift a group of cells depending on their voltage threshold. As a result of this corrective sense operation, the read window budget (RWB) for the group may improve, which can improve system operation (e.g., ensure the data states of the memory cells are not erroneously sensed).

As described further herein, a corrective read operation can be performed on groups of memory cells over time. The cells coupled to an access (e.g., word) line experiencing a corrective read can be referred to as victim cells, and can be separated into two groups: a low voltage and high voltage group. This separation of the two groups can be based on the threshold voltage (Vt) of the memory cells coupled to the neighboring (e.g., directly adjacent) word lines, which can be referred to as aggressor cells. A low voltage group will experience more threshold voltage downshift due to lateral charge loss, compared to a high voltage group.

In previous approaches, a corrective read operation may include six reads to sense four bits of data from memory cells coupled to the word lines adjacent a selected word line (e.g., three reads to sense two bits from one of the adjacent word lines, and three reads to sense two bits from the other), which define four regions from each word line. Then 16 reads (e.g., one for each combined region) can be performed to sense the data from the group of memory cells coupled to the selected word line, for a total of 22 reads. Such a large number of reads can increase the read timing of the corrective read operation, which can cause system timeout and other performance issues.

In contrast, embodiments of the present disclosure address the above and other deficiencies by reducing the read timing in a corrective read operation within a memory system by reducing the number of reads performed in the corrective read operation. For example, embodiments of the present disclosure can reduce the number of line reads from 16 to 7, thereby reducing the corrective read time significantly, which can prevent system timeout issues and increase the performance of the memory system.

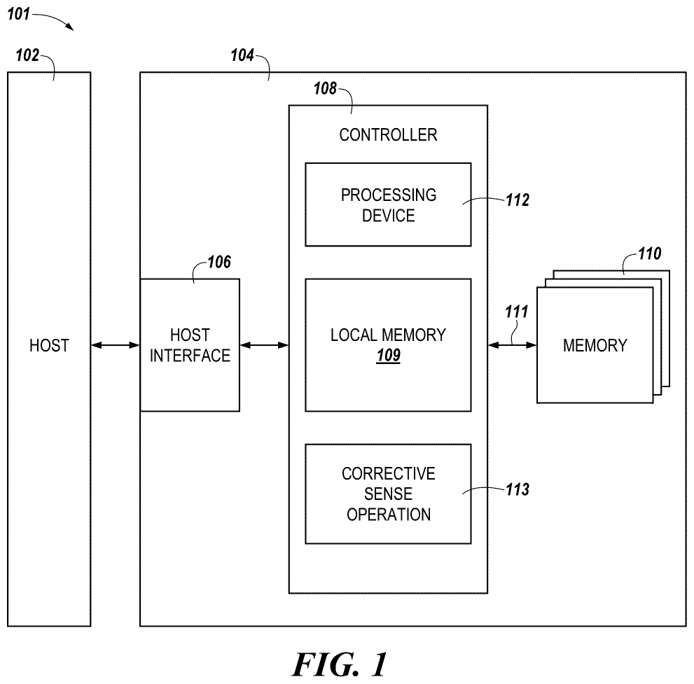

FIG. 1 illustrates an example computing environment 101 that includes a memory sub-system 104 in accordance with some embodiments of the present disclosure. The memory sub-system 104 can include media, such as memory components 110. The memory components 110 can be volatile memory components, non-volatile memory components, or a combination of such. In some embodiments, the memory sub-system is a storage system. An example of a storage system is an SSD. In some embodiments, the memory sub-system 104 is a hybrid memory/storage sub-system. In general, the computing environment 100 can include a host system 102 that uses the memory sub-system 104. For example, the host system 102 can write data to the memory sub-system 104 and read data from the memory sub-system 104.

The host system 102 can be a computing device such as a personal laptop computer, a desktop computer, a digital camera, a mobile telephone, or a memory card reader, among various other types of hosts. The host system 102 can include or be coupled to the memory sub-system 104 (e.g., via a host interface 106) so that the host system 102 can read data from or write data to the memory subsystem 104. As used herein, “coupled to” generally refers to a connection between components, which can be an indirect communicative connection or direct communicative connection (e.g., without intervening components), whether wired or wireless, including connections such as electrical, optical, magnetic, etc. The host interface 106 can be a physical interface, examples of which include, but are not limited to, a serial advanced technology attachment (SATA) interface, a peripheral component interconnect express (PCIe) interface, universal serial bus (USB) interface, Fibre Channel, Serial Attached SCSI (SAS), etc. The host interface 106 can be used to transmit data between the host system 102 and the memory sub-system 104. The host system 102 can further utilize an NVM Express (NVMe) interface to access the memory components 110 when the memory sub-system 104 is coupled with the host system 102 by a PCIe interface. The physical host interface can provide an interface for passing control, address, data, and other signals between the memory sub-system 104 and the host system 102. The memory components 110 can include a number of arrays of memory cells (e.g., non-volatile memory cells). The arrays can be flash arrays with a NAND architecture, for example. However, embodiments are not limited to a particular type of memory array or array architecture. Although floating-gate type flash memory cells in a NAND architecture are generally referred to herein, embodiments are not so limited. The memory cells can be grouped, for instance, into a number of blocks including a number of physical pages. A number of blocks can be included in a plane of memory cells and an array can include a number of planes. As one example, a memory device can be configured to store 8 KB (kilobytes) of user data per page, 128 pages of user data per block, 2048 blocks per plane, and 16 planes per device. The memory components 110 can also include additionally circuitry (not illustrated), such as control circuitry, buffers, address circuitry, etc.

In operation, data can be written to and/or read from memory (e.g., memory components 110 of system 104) as a page of data, for example. As such, a page of data can be referred to as a data transfer size of the memory system. Data can be sent to/from a host (e.g., host 102) in data segments referred to as sectors (e.g., host sectors). As such, a sector of data can be referred to as a data transfer size of the host.

The memory components 110 can include various combinations of the different types of non-volatile memory components and/or volatile memory components. An example of non-volatile memory components includes a negative-and (NAND) type flash memory. The memory components 110 can include one or more arrays of memory cells such as single level cells (SLCs) or multi-level cells (MLCs) (e.g., triple level cells (TLCs) or quad-level cells (QLCs)). In some embodiments, a particular memory component can include both an SLC portion and a MLC portion of memory cells. Each of the memory cells can store one or more bits of data (e.g., data blocks) used by the host system 102. Although non-volatile memory components such as NAND type flash memory are described, the memory components 110 can be based on various other types of memory such as a volatile memory. In some embodiments, the memory components 110 can be, but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. Furthermore, the memory cells of the memory components 110 can be grouped as memory pages or data blocks that can refer to a unit of the memory component used to store data.

As illustrated in FIG. 1, the memory sub-system 104 can include a controller 108 coupled to the host interface 106 and to the memory components 110 via a memory interface 111. The controller 108 can be used to send data between the memory sub-system 104 and the host 102. The memory interface 111 can be one of various interface types compliant with a particular standard such as Open NAND Flash interface (ONFi).

The controller 108 can communicate with the memory components 110 to perform operations such as reading data, writing data, or erasing data at the memory components 110 and other such operations. The controller 108 can include hardware such as one or more integrated circuits and/or discrete components, a buffer memory, or a combination thereof. The controller 108 can be a microcontroller, special purpose logic circuitry (e.g., a field-programmable gate array (FPGA), an application-specific integrated circuit (ASIC), etc.), or other suitable processor. The controller 108 can include a processing device 112 (e.g., processor) configured to execute instructions stored in local memory 109. In the illustrated example, the local memory 109 of the controller 108 includes an embedded memory configured to store instructions for performing various processes, operations, logic flows, and routines that control operation of the memory sub-system 104, including handling communications between the memory sub-system 104 and the host system 102. In some embodiments, the local memory 109 can include memory registers storing memory pointers, fetched data, etc. The local memory 109 can also include read-only memory (ROM) for storing micro-code.

While the example memory sub-system 104 in FIG. 1 has been illustrated as including the controller 108, in another embodiment of the present disclosure, a memory sub-system 104 may not include a controller 108, and can instead rely upon external control (e.g., provided by an external host, such as by a processing device separate from the memory sub-system 104).

The controller 108 can use and/or store various operating parameters associated with operating (e.g., programming and/or reading) the memory cells. Such operating parameters may be referred to as trim values and can include programming pulse magnitude, step size, pulse duration, program verify voltages, read voltages, etc. for various different operating processes. The different processes can include processes to program cells to store different quantities of bits, and different multiple pass programming process types (e.g., 2-pass, 3-pass, etc.). The controller 108 can be responsible for other operations such as wear leveling operations, garbage collection operations, error detection and/or correction (e.g., error-correcting code (ECC)) operations, encryption operations, caching operations, and address translations between a logical block address and a physical block address that are associated with the memory components 110.

The memory sub-system 104 can also include additional circuitry or components that are not illustrated. For instance, the memory components 110 can include control circuitry, address circuitry (e.g., row and column decode circuitry), and/or input/output (I/O) circuitry by which they can communicate with controller 108 and/or host 102. As an example, in some embodiments, the address circuitry can receive an address from the controller 108 and decode the address to access the memory components 110.

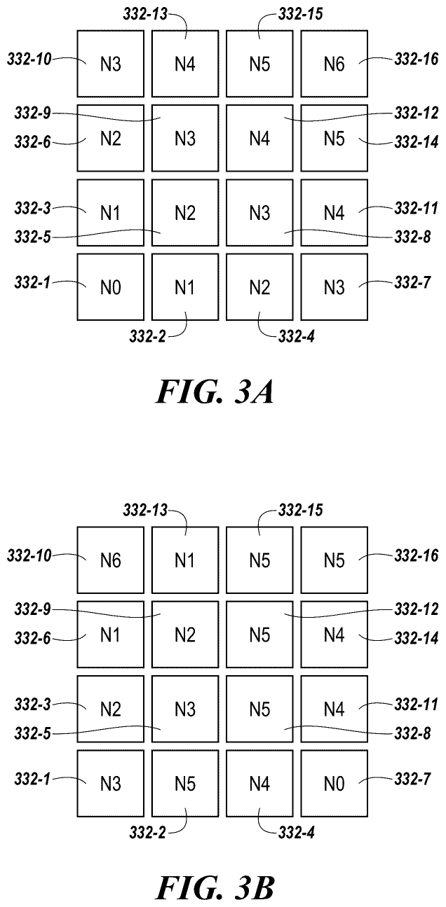

In various embodiments, the controller 108 can include a corrective sense operation component 113 to perform corrective sense operations in accordance with the present disclosure. For example, a sense operation may be performed on a plurality of groups of memory cells of a memory component 110. A threshold voltage value of the memory cells can be determined based on the sense operation, and corrective sense operation component 113 can sort the memory cells into the plurality of groups based on their threshold voltage values. For instance, a number of the groups within the plurality of groups of memory cells can be binned together by corrective sense operation component 113 based on the threshold voltage value of their neighboring memory cells (e.g., the memory cells coupled to the word lines that are directly adjacent to the word lines to which the memory cells of the groups are coupled). This process may be performed on multiple pluralities of groups in some embodiments. Examples of binning groups of memory cells together will be further described herein (e.g., in connection with FIGS. 3A and 3B).

In various embodiments, the corrective sense operation component 113 can perform a corrective sense operation on a first one of the plurality of groups of memory cells using a corrective value. In some examples, the corrective sense operation component 113 can perform the corrective sense operation on a second one of the plurality of groups of memory cells using the corrective value. For instance, corrective sense operation component 113 can perform the corrective sense operation on the number of groups of memory cells that have been binned together (e.g., the first and second groups of memory cells are groups that have been binned together) using the corrective value. The corrective value can be used to adjust the sensing (e.g., read) voltage used in the corrective sense operation (e.g., the same adjusted read voltage can be used on each group of cells that have been binned together). Performing the corrective sense operation can, for example, prevent the memory component 110 from experiencing timeout.

In various embodiments, the corrective sense operation component 113 can determine an error rate (e.g., bit error rate) associated with the sense operation performed on the plurality of groups of memory cells and can perform the corrective sense operation based on the error rate. For example, the corrective sense operation component 113 can perform the corrective sense operation responsive to the error rate meeting or exceeding a threshold error rate (e.g., responsive to the error rate meeting or exceeding the threshold error rate for at least one of the plurality of groups of memory cells). Corrective sense operation component 113 can determine the error rate at a particular point in time during the lifetime of memory sub-system 104, at particular time intervals during the lifetime of memory sub-system 104, or responsive to the groups of memory cells undergoing a threshold amount of corrective sense operations, for example.

The corrective sense operation component 113 can perform the corrective sense operation on additional ones of the plurality of groups of memory cells (e.g., other groups that have been binned together with the first and second groups). For instance, the corrective sense operation component 113 can perform the corrective sense operation on a third one of the plurality of groups of memory cells using the corrective value. The threshold voltage value of the memory cells of these groups of memory cells on which the corrective sense operation is performed may have shifted due to charge loss. For example, the threshold voltage value of the memory cells of a first subgroup of the groups may have shifted less than the threshold voltage value of the memory cells of a second subgroup of the groups.

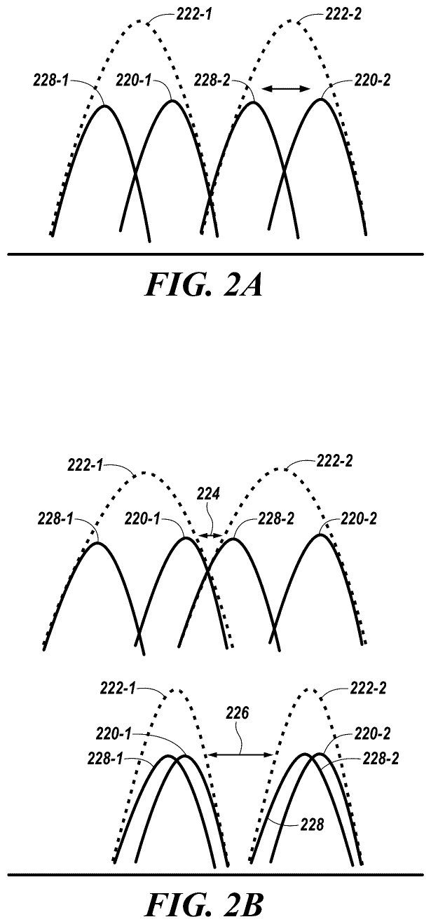

In various embodiments, the corrective value may compensate for a shift that has occurred in the threshold voltage value of the memory cells of these groups on which the corrective sense operation is performed. For example, the corrective value may shift up a threshold voltage distribution associated with one (e.g., the first) of the plurality of groups of memory cells, and may also shift down a threshold voltage distribution associated with another (e.g., the second) one of the plurality of groups of memory cells. As an additional example, the corrective sense (e.g. read) value can be equal to a voltage amount that reduces an error rate associated with the sense operation on the plurality of groups of memory cells by a threshold amount. The corrective sense operation can be performed using a range of (e.g., seven) different sensing voltages. An example illustrating threshold voltage distributions of groups of memory cells on which a corrective sense operation is to be performed, and has subsequently been performed, will be further described herein (e.g., in connection with FIGS. 2A-2B).

FIG. 2A illustrates a diagram of a number of initial threshold voltage (Vt) distributions associated with groups of memory cells in accordance with some embodiments of the present disclosure. For instance, FIG. 2A illustrates threshold voltage distributions associated with groups of memory cells immediately following the programming of the memory cells to their respective data states.

The groups of memory cells can be, for instance, the first group and second group of memory cells previously described in connection with FIG. 1. For example, the Vt distributions 222-1 and 222-2 correspond to the data states of all memory cells of the first and second group, the Vt distributions 228-1 and 228-2 correspond to the data states of the first one of the plurality of groups, and Vt distributions 220-1 and 220-2 correspond to the data states of the second one of the plurality of groups. FIG. 2A illustrates the Vt distributions of each group of cells compared to all cells before downshift or loss of charge.

Vt distributions 222-1 and 222-2 shown in FIG. 2A represent two target data states to which the memory cells of the groups can be programmed. For instance, Vt distribution 222-1 can represent data state 0, and Vt distribution can represent data state 1. That is, the Vt distributions illustrated in FIG. 2A can correspond to single level (e.g., two state) memory cells. However, embodiments of the present disclosure are not limited to these data assignments or single level memory cells, as previously described herein.

Vt distributions 222-1 and 222-2 can represent a quantity (e.g., number) of memory cells programmed to the corresponding target states (e.g., 0 and 1, respectively), with the height of each Vt distribution curve indicating the quantity of cells programmed to a particular voltage within the Vt distribution. For instance, Vt distributions 228-1 and 228-2 represent the quantity of memory cells of the first group programmed to data states 0 and 1, respectively, and Vt distributions 220-1 and 220-2 represent the quantity of memory cells of the second group programmed to data states 0 and 1, respectively. That is, the threshold voltages of the memory cells of the first group are lower within their respective Vt distributions than the threshold voltages of the memory cells of the second group, as illustrated in FIG. 2A. As such, the first group of memory cells can be referred to as a low voltage group, and the second group of memory cells can be referred to as a high voltage group. The width of each Vt distribution curve indicates the range of voltages that represent a target state.

FIG. 2B illustrates a diagram of a number of threshold voltage distributions (e.g., Vt distributions 222-1 and 222-2, Vt distributions 228-1 and 228-2, and Vt distributions 220-1 and 220-2) associated with the groups of memory cells before a corrective sense operation (e.g., corrective read), and a number of threshold voltage distributions associated with the groups of memory cells after the corrective sense operation in accordance with some embodiments of the present disclosure. For instance, the top portion of FIG. 2B illustrates the Vt distributions before the corrective read, and the bottom portion of FIG. 2B illustrates the Vt distributions after the corrective read.

As shown in the top portion of FIG. 2B, subsequent operation (e.g., sensing) of the memory cells after they were programmed has resulted in the Vt distributions 228-1, 228-2, 220-1, and 220-2 widening, which has resulted in Vt distributions 222-1 and 222-2 becoming closer together and overlapping, as indicated by arrow 224. This may result in memory cells that were originally programmed to one data state being erroneously sensed to be storing a different data state.

However, as shown in the bottom portion of FIG. 2B, a corrective sense operation performed on the groups of memory cells has resulted in the Vt distributions 228-1 and 228-2 shifting up (e.g., to the right), which has resulted in Vt distributions 222-1 and 222-2 becoming further apart such that they do not overlap, as indicated by arrow 226. As an additional example, Vt distributions 220-1 and 220-2 can shift down (e.g., instead of Vt distributions 228-1 and 228-2 shifting up), which would also result in Vt distributions 222-1 and 222-2 becoming further apart and not overlapping. As such, the corrective sense operation can ensure that the data states of the memory cells are not erroneously sensed.

FIG. 3A illustrates a conceptual example of binning groups of memory cells together for corrective sense (e.g., read) operations in accordance with some embodiments of the present disclosure. As mentioned previously in connection with FIG. 1, groups of memory cells can be binned together based on a threshold voltage value of their memory cells. Each bin can be based on a threshold voltage value shared by the cells within each group, and the same adjusted sensing (e.g., read) voltage can be used on the groups of cells in each respective bin during a corrective sense operation. In the example illustrated in FIG. 3A, groups 332-2 and 332-3 are binned together (e.g., in bin N1), groups 332-4, 332-5, and 332-6 are binned together (e.g., in bin N2), groups 332-7, 332-8, 332-9, and 332-10 are binned together (e.g., in bin N3), groups 332-11, 332-12, and 332-13 are binned together (e.g., in bin N4), and groups 332-14 and 332-15 are binned together (e.g., in bin N5). Further, group 332-1 comprises bin N0, and group 332-16 comprises bin N6 (e.g., groups 332-1 and 332-16 are not binned together with any other groups).

FIG. 3B illustrates an additional conceptual example of binning groups of memory cells together for corrective sense (e.g., read) operations in accordance with some embodiments of the present disclosure. As previously mentioned in FIGS. 1 and 3A, groups of memory cells can be binned together based on a threshold voltage value of their memory cells. Each bin can be based on a threshold voltage value shared by the cells within each group, and the same adjusted sensing (e.g., read) voltage can be used on the groups of cells in each respective bin during a corrective sense operation. In the second example illustrated in FIG. 3B, groups 332-6 and 332-13 are binned together (e.g., in bin N1), groups 332-3 and 332-9 are binned together (e.g., in bin N2), groups 332-1 and 332-5 are binned together (e.g., in bin N3), groups 332-4, 332-11, and 332-14 are binned together (e.g., in bin N4), and groups 332-2, 332-8, 332-12, 332-15, and 332-16 are binned together (e.g., in bin N5). Further, group 332-7 comprises bin N0, and group 332-13 comprises bin N6 (e.g., groups 332-7 and 332-13 are not binned together with any other groups). In the example illustrated in FIG. 3B, the coupling to coupling (C2C) effect of one adjacent word line on a selected word line may be different than the C2C effect of the other adjacent word line on a selected word line, and as such the binning of the groups is not perfectly diagonal (e.g., as it is in FIG. 3A).

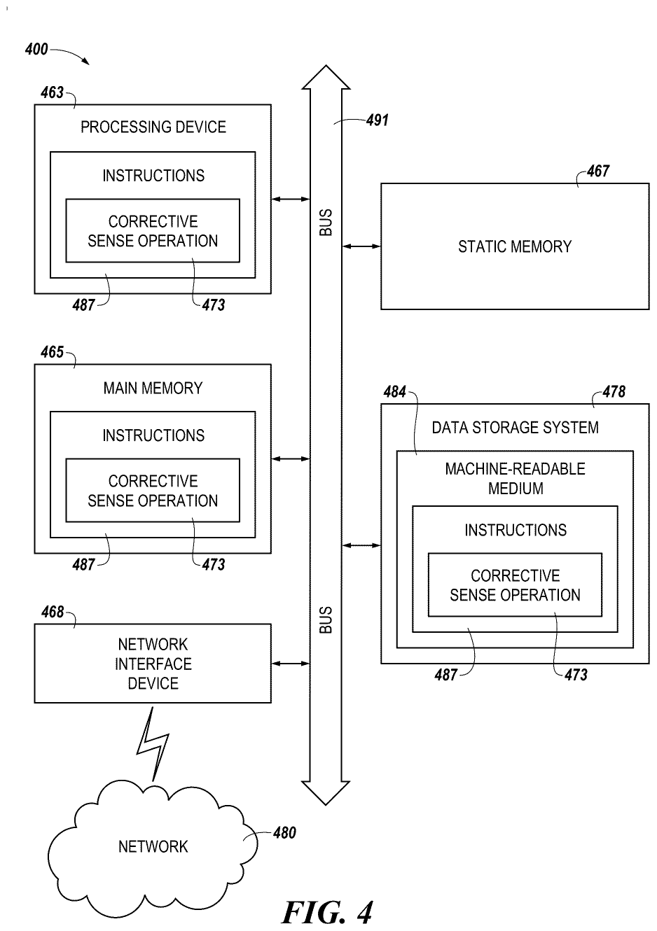

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 102 of FIG. 1) that includes, is coupled to, or utilizes a memory sub-system (e.g., the memory sub-system 104 of FIG. 1) or can be used to perform the operations of a controller (e.g., a corrective sense operation in accordance with the present disclosure). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 463, a main memory 465 (e.g., read-only memory (ROM), flash memory, dynamic random access memory (DRAM) such as synchronous DRAM (SDRAM) or Rambus DRAM (RDRAM), etc.), a static memory 467 (e.g., flash memory, static random access memory (SRAM), etc.), and a data storage system 478, which communicate with each other via a bus 491.

Processing device 463 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 463 can also be one or more special-purpose processing devices such as an application specific integrated circuit (ASIC), a field programmable gate array (FPGA), a digital signal processor (DSP), network processor, or the like. The processing device 463 is configured to execute instructions 487 for performing a corrective sense operation 473 as discussed herein. The computer system 400 can further include a network interface device 468 to communicate over the network 480.

The data storage system 478 can include a machine-readable storage medium 484 (also known as a computer-readable medium) on which is stored one or more sets of instructions 487 or software embodying any one or more of the methodologies or functions described herein. The instructions 487 can also reside, completely or at least partially, within the main memory 465 and/or within the processing device 463 during execution thereof by the computer system 400, the main memory 465 and the processing device 463 also constituting machine-readable storage media. The machine-readable storage medium 484, data storage system 478, and/or main memory 465 can correspond to the memory sub-system 104 of FIG. 1.

In one embodiment, the instructions 487 include instructions to implement functionality corresponding to a corrective sense operation (e.g., corrective sense operation component 113 of FIG. 1). While the machine-readable storage medium 484 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a memory component including a plurality of groups of memory cells; and
a processing device coupled to the memory component and configured to:
perform a sense operation on the plurality of groups of memory cells;
perform a corrective sense operation on a first one of the plurality of groups of memory cells using a corrective value; and
perform the corrective sense operation on a second one of the plurality of groups of memory cells using the corrective value.

2. The apparatus of claim 1, wherein the processing device is configured to:
determine an error rate associated with the sense operation performed on the plurality of groups of memory cells; and
perform the corrective sense operation based on the error rate.

3. The apparatus of claim 1, wherein the first one of the plurality of groups of memory cells and the second one of the plurality of groups of memory cells are binned together based on a threshold voltage value of their neighboring memory cells.

4. The apparatus of claim 1, wherein the processing device is configured to perform the corrective sense operation on a third one of the plurality of groups of memory cells using the corrective value.

5. The apparatus of claim 1, wherein a threshold voltage value of the memory cells of the first one of the plurality of groups and the second one of the plurality of groups have shifted due to charge loss.

6. The apparatus of claim 5, wherein the threshold value of the memory cells of a first subgroup of the first one of the plurality of groups and the second one of the plurality of groups have shifted less than the threshold voltage value of the memory cells of a second subgroup of the first one of the plurality of groups and the second one of the plurality of groups.

7. The apparatus of claim 1, wherein the processing device is configured to sort the memory cells into the plurality of groups based on a threshold voltage value of the memory cells.

8. A method, comprising:
performing a sense operation on a plurality of groups of memory cells within a memory device;
performing a corrective sense operation on a first one of the plurality of groups of memory cells using a corrective value; and
performing the corrective sense operation on a second one of the plurality of groups of memory cells using the corrective value.

9. The method of claim 8, wherein the corrective value shifts up a threshold voltage distribution associated with the first one of the plurality of groups of memory cells.

10. The method of claim 8, wherein the corrective value shifts down a threshold voltage distribution associated with the second one of the plurality of groups of memory cells.

11. The method of claim 8, wherein the method includes performing the corrective sense operation on the first and second ones of the plurality of groups of memory cells using a plurality of different sense voltages.

12. The method of claim 8, wherein performing the corrective sense operation on the first and second ones of the plurality of groups of memory cells using the corrective value prevents the memory device from experiencing timeout.

13. The method of claim 8, wherein the corrective value compensates for a shift that has occurred in a threshold voltage value of the memory cells of the first one of the plurality of groups and the second one of the plurality of groups.

14. The method of claim 8, wherein the corrective value is equal to a voltage amount that reduces an error rate associated with the sense operation performed on the plurality of groups of memory cells by a threshold amount.

15. A system, comprising:
a memory component including a plurality of groups of memory cells; and
a processing device coupled to the memory component and configured to:
perform a sense operation on the plurality of groups of memory cells;
bin a number of groups of the plurality of groups of memory cells together based on a threshold voltage value of the memory cells of the number of groups; and
perform a corrective sense operation on the number of groups of memory cells using a corrective value.

16. The system of claim 15, wherein the processing device is configured to:
determine an error rate associated with the sense operation performed on the plurality of groups of memory cells; and
perform the corrective sense operation responsive to the error rate meeting or exceeding a threshold error rate.

17. The system of claim 16, wherein the processing device is configured to perform the corrective sense operation responsive to the error rate meeting or exceeding the threshold error rate for at least one of the plurality of groups of memory cells.

18. The system of claim 16, wherein the processing device is configured to determine the error rate at a particular point in time during a lifetime of the system.

19. The system of claim 16, wherein the processing device is configured to determine the error rate at particular time intervals during a lifetime of the system.

20. The system of claim 16, wherein the processing device is configured to determine the error rate responsive to the groups of memory cells undergoing a threshold amount of corrective sense operations.
